(19) United States
(12) Patent Application Publication
(10) Pub. No.: US 2012/0312366 A1
(43) Pub. Date: Dec. 13, 2012

(54) FIRE RESISTANT BACK-SHEET FOR PHOTOVOLTAIC MODULE

(75) Inventors: Adam Ben Starry, Kennett Square, PA (US); Brian C. Auman, Avondale, PA (US); Carl Robert Haeger, Reynoldsburg, OH (US); Roger Curtis Wicks, Colonial Heights, VA (US)

(73) Assignee: E. I. DU PONT DE NEMOURS AND COMPANY, Wilmington, DE (US)

(21) Appl. No.: 13/315,326

(22) Filed: Dec. 9, 2011

Related U.S. Application Data
(60) Provisional application No. 61/425,837, filed on Dec. 22, 2010.

(51) Int. Cl. B32B 19/04; H01L 31/0203

(52) U.S. Cl. 136/256; 428/331; 428/324; 442/1

(57) ABSTRACT

A back-sheet for a photovoltaic module comprises a fire resistant sheet adhered to a fluoropolymer film. The fire resistant sheet comprises 40 to 100 weight percent of crystallized mineral silicate platelets based on the weight of the fire resistant sheet, and the fire resistant sheet has an average thickness of at least 75 microns, and more preferably at least 100 microns. The crystallized mineral silicate platelets of the fire resistant sheet are selected from the group of mica, vermiculite, clay, talc, and combinations thereof. A photovoltaic module made with such a back-sheet is also disclosed.

### FIELD OF THE INVENTION

The present invention relates to back-sheet laminates for photovoltaic modules, and more particularly to fire resistant back-sheet laminates. The invention also relates to photovoltaic modules incorporating such fire resistant back-sheet laminates.

### BACKGROUND OF THE INVENTION

As a renewable energy resource, the use of photovoltaic modules is rapidly expanding. A photovoltaic module (also known as a solar cell module) refers to a photovoltaic device for generating electricity directly from light, particularly, from sunlight. With increasing use of photovoltaic modules, comes an increased demand for photovoltaic modules suitable for use in demanding environments. Photovoltaic modules are normally installed in outdoor locations such as on a roof, wall or other supporting structure. Many climate areas where sunlight is plentiful are also places where fire is of concern. Photovoltaic modules installed on building exteriors in fire prone areas may need to be fire resistant.

As shown in FIG. 1, a photovoltaic module 10 comprises a light-transmitting substrate 12 or front sheet, an encapsulant layer 14, an active photovoltaic cell layer 16, another encapsulant layer 18 and a back-sheet 20. The light-transmitting substrate or front sheet, which is also known as the incident layer, is typically glass or a durable light-transmitting polymer film. The encapsulant layers 14 and 18 adhere the photovoltaic cell layer 16 to the front and back sheets and they seal and protect the photovoltaic cells from moisture and air. The encapsulant layers 14 and 18 are typically comprised of a thermoplastic or thermosetting resin such as ethylene-vinyl acetate copolymer (EVA). The photovoltaic cell layer 16 may be any type of solar cell that converts sunlight to electric current such as single crystal silicon solar cells, polycrystalline silicon solar cells, microcrystalline silicon solar cells, amorphous silicon-based solar cells, copper indium (gallium) diselenide solar cells, cadmium telluride solar cells, compound semiconductor solar cells, dye sensitized solar cells, and the like. The back-sheet 20 provides structural support for the module 10, it electrically insulates the module, and it helps to protect the module wiring and other components against the elements, including heat, water vapor, oxygen and UV radiation. The back-sheet needs to remain intact and adhered to the encapsulant for the service life of the photovoltaic module, which may extend for multiple decades.

Multilayer laminates have been employed as photovoltaic module back-sheets. One or more of the laminate layers in such back-sheets conventionally comprise a highly durable and long lasting polyvinyl fluoride (PVF) film which is available from E. I. du Pont de Nemours and Company as Tedlar® film. PVF films resist degradation by sunlight, they provide a good moisture barrier, and they are less prone to burning or melting than films made of many other polymers. PVF films are typically laminated to other less costly polymer films that contribute mechanical and dielectric strength to the back-sheet, such as polyester films, as for example polyethylene terephthalate (PET) films. Other conventional back-sheet laminates are comprised wholly of polyester films, but such back-sheets have been found to experience delamination and they are less resistant to heat and fire than PVF-based films. Conventional back-sheet polymer films, including PVF films and PET films, will burn or melt when exposed to an open flame. Fire resistant back-sheet laminates have been made that incorporate metal foils (US Patent Application Publication No. 2008-0053512) or metal plates (Japan Patent Application Publication No. 2001-036-116). However metal foils and plates are difficult to permanently adhere to other polymer back-sheet layers and they can hinder the electrical insulation properties of the back-sheet.

There is a need for a back-sheet for photovoltaic module that does not readily burn or melt when exposed to fire. There is also a need for such a back-sheet laminate that resists delamination over long periods of time. There is a further need for a back-sheet that offers excellent moisture resistance, durability, and heat and fire resistance.

### SUMMARY OF THE INVENTION

A back-sheet for a photovoltaic module comprises a fire resistant sheet adhered to a fluoropolymer film. The fire resistant sheet comprises 40 to 100 weight percent of crystallized mineral silicate platelets based on the weight of the fire resistant sheet, and the fire resistant sheet has an average thickness of at least 75 microns, and more preferably at least 100 microns. The crystallized mineral silicate platelets of the fire resistant sheet are selected from the group of mica, vermiculite, clay, talc, and combinations thereof. A photovoltaic module made with such back-sheet is also disclosed.

In one embodiment, the crystallized mineral silicate platelets are mica platelets that comprise at least 70% by weight of the flame resistant sheet. In another embodiment, the crystallized mineral silicate platelets are vermiculite platelets that comprise at least 70% by weight of the flame resistant sheet.

The crystallized mineral silicate platelets of the fire resistant sheet may have an average diameter of about 1 to about 500 microns and an average thickness of about 0.01 to about 2 microns, where the average diameter of the mineral silicate platelets is from about 20 to about 300 times greater than the average thickness of the platelets.

The fire resistant sheet may further comprise an inorganic support scrim such as a scrim comprised of glass fibers.

The fire resistant sheet may be a paper comprising polymer fibrids that do not melt at temperatures below 280° C., and more preferably do not melt at temperatures below 300° C. This fire resistant paper may comprise meta-aramid fibrids and at least 50% by weight of crystallized mineral silicate platelets based on the weight of the fire resistant sheet. The crystallized mineral silicate platelets may be mica particles. The fire resistant paper may further comprise a meta-aramid floc. The fibrids or floc of the fire resistant polymeric paper sheet may further comprise an organic or an inorganic flame retardant, and combinations thereof.

The fluoropolymer film of the back-sheet is preferably a film consisting essentially of fluoropolymer selected from polyvinylfluoride, polyvinylidene fluoride, polytetrafluoroethylene, ethylene-tetrafluoroethylene and combinations thereof. According to one aspect, the fire resistant sheet has two opposite sides, the first side of which is adhered to the fluoropolymer film, and the second side of which is adhered to a second polymeric film. The second polymeric film is preferably a film selected from fluoropolymer films or polyester films.

### BRIEF DESCRIPTION OF THE DRAWINGS

The detailed description will refer to the following drawings, wherein like numerals refer to like elements:

FIG. 1 is a cross-sectional view of one particular embodiment of a photovoltaic module;

FIG. 2 is a cross-sectional view of the fire resistant back-sheet disclosed herein;

FIG. 3 shows a testing arrangement for testing the fire resistant properties of back-sheet laminate structures.

### DETAILED DESCRIPTION OF THE INVENTION

To the extent permitted by the United States law, all publications, patent applications, patents, and other references mentioned herein are incorporated by reference in their entirety.

The materials, methods, and examples herein are illustrative only and the scope of the present invention should be judged only by the claims.

### Definitions

The following definitions are used herein to further define and describe the disclosure.

As used herein and recited in the claims, the term “a” includes the concepts of “at least one” or “one or more than one”.

Unless stated otherwise, all percentages, parts, ratios, etc., are by weight.

When the term “about” is used in describing a value or an end-point of a range, the disclosure should be understood to include the specific value or end-point referred to.

The terms “sheet” and “layer” are used in their broad sense interchangeably. A “back-sheet” is a sheet, layer or planar laminate on the side of a photovoltaic module that faces away from a light source, and is generally opaque. In some instances, it may be desirable to receive light from both sides of a device (e.g., a bifacial device), in which case a module may have transparent layers on both sides of the device.

“Encapsulant” layers are used to encase the fragile voltage-generating solar cell layer to protect it from environmental or physical damage and hold it in place in the photovoltaic module. Encapsulant layers may be positioned between the solar cell layer and the front sheet incident layer, between the solar cell layer and the back-sheet backing layer, or both. Suitable polymer materials for these encapsulant layers typically possess a combination of characteristics such as high transparency, high impact resistance, high penetration resistance, high moisture resistance, good ultraviolet (UV) light resistance, good long term thermal stability, adequate adhesion strength to front-sheets, back-sheets, other rigid polymeric sheets and cell surfaces, and good long term weatherability.

The term “copolymer” is used herein to refer to polymers containing copolymerized units of two different monomers (a dipolymer), or more than two different monomers.

A back-sheet for a photovoltaic module is disclosed. The disclosed back-sheet comprises a fire resistant sheet and a fluoropolymer film adhered to the fire resistant sheet. The fire resistant sheet comprises 40 to 100 weight percent of crystallized mineral silicate platelets based on the weight of the fire resistant sheet, where the fire resistant sheet has an average thickness of at least 75 microns, and preferably at least 90 microns, and even more preferably at least 100 microns.

The term platelet is used to refer to flat disc or generally oval shaped planar particles that are significantly longer and wider than they are thick. The preferred mineral silicate platelets have an average diameter, length or width of about 1 to about 500 microns and a thickness of about 0.01 to about 2 microns. Where the platelets are disc shaped the length and width of the particles is similar, and where the platelets have a generally oval shape, the length of the particles may be 1.5 to 5 times the width of the particles. The average particle diameter or length of the mineral silicate platelets is typically from about 20 to about 300 times greater than the thickness of the platelets. Preferred crystallized mineral silicate platelets particles have an average particle diameter from about 10 to about 150 microns, and an average thickness of about 0.05 to about 1 micron. If the particle size is too large, the particles may add surface roughness to the paper or sheet. If the particle size is too small, the particles may be difficult to disperse and the viscosity may be excessively high.

The crystallized mineral silicate platelets of the flame resistant sheet may be selected from the group of mica, vermiculite, clay, talc, and combinations thereof. Platelet-shaped particles of mica and vermiculite are particularly useful as they are inexpensive, disperse well and yield favorable electrical, mechanical and fire resistance properties.

Various micas (eg. muscovite, phlogopite and synthetic) are available commercially. Mica is a well-known crystallized mineral silicate available in a variety of monoclinic forms that readily separate into very thin leaves or plates. Many micas may have the general formula X₂Y₄₋₆Z₈O₂₀(OH,F)₄ in which X is K, Na, Ca, Ba, Rb, or Cs; Y is Al, Mg, Fe, Mn, Cr, Ti or Li; and Z is chiefly Si or Al, but may also include Fe³⁺ or Ti. Examples of micas are grannitic potassium mica represented by typical chemical formulae K₂Al₄Al₂Si₆O₂₂(OH)₄ and H₂KAl₃(SiO₄)₃ and pyroxenic mica (magnesium mica) represented by typical formulae K₂Mg₄Al₂Si₆O₂₀(OH)₄ and H₂KMg₃Al(SiO₄)₃. Micas most useful in practice of this invention has a flat particle average diameter of 30 to 500 microns and an average thickness of 0.05 to 1 micron.

Vermiculite is a natural mineral that expands with the application of heat. Vermiculite is a platelet shaped phyllosilicate represented by the typical formula (MgFe,Al)₃(Al,Si)₄O₁₀(OH)₂4H₂O.

In one aspect, the crystallized mineral silicate platlet particles are mixed in an aqueous dispersion and then drawn down on a polymer film or other scrim to produce a wet film of the particles with a thickness of roughly 40 mil. The wet particle film is dried overnight at room temperature and then dried over a second night at about 120° C. to remove residual moisture. By this process, a dry sheet of crystallized mineral silicate platlet particles with a thickness of about 3 to 8 mils can be produced. In order to increase the strength, durability and handling capacity, the sheet of dried crystallized mineral silicate platelet particles can be impregnated with binder such as a silicone resin or a polyurethane. Preferably, such binder comprises no more that 20% by weight of the dried sheet, and more preferably the binder comprises no more that 10% by weight of the dried sheet This sheet serves as the fire resistant sheet of a back-sheet laminate structure and it can be adhered to a fluoropolymer film and/or other film, such as a polyester film for increased strength, durability and moisture barrier properties.

In another aspect, the fire resistant sheet may comprise a sheet of crystallized mineral silicate platelets that is formed from dispersion as described above, but on an inorganic scrim or sheet such as a fiberglass sheet. In this aspect, the inorganic scrim or film serves to strengthen the dried sheet of crystallized mineral silicate platelet particles. In preferred embodiments, the fire resistant sheet comprises a layer of dried mica or vermiculite particles formed and dried on a glass fiber scrim. One such sheet is a glass backed mica sheet available from PAMICA Electric Material (Hubei) Co., Ltd., of Xianning, China under the product code S140G32. In certain preferred aspects, the flame resistant sheet is comprised of at least 50% by weight of crystallized mineral silicate platelet particles based on the weight of the flame resistant sheet, and more preferably at least 75% by weight of crystallized mineral silicate platelet particles based on the weight of the flame resistant sheet.

The fire resistant sheet of the back-sheet laminate for a photovoltaic module may further comprise polymer fibrids that do not melt or burn at temperatures below 280° C., and more preferably do not melt or burn at temperatures below 300° C. One such fibrid is an arimid fibrid. The term “aramid” is used to mean aromatic polyamide, wherein at least 85% of the amide (—CONH—) linkages are attached directly to aromatic rings. Aramids may include up to 10 percent by weight of other polymers blended with the aramid. Aramids may have as much as 10 percent of other diamines substituted for the diamine of the aramid or as much as 10 percent of other diacid chlorides substituted for the diacid chloride of the aramid.

The term “fibrid” is used to mean very small, nongranular, fibrous or film-like particles with at least one of their three dimensions being of minor magnitude relative to the largest dimension. These particles are prepared by precipitation of a solution of polymeric material using a non-solvent under high shear. The term “aramid fibrids” means non-granular film-like particles of aromatic polyamide having a melting point or decomposition point above 320° C. The fibrids generally have a largest dimension length in the range of about 0.2 mm to about 1 mm with a length-to-width aspect ratio of about 5:1 to about 10:1. The thickness dimension is on the order of a fraction of a micron, for example, about 0.1 microns to about 1.0 micron.

A slurry of aramid fibrids and crystallized mineral silicate platelets can be formed into a fire resistant paper sheet using a conventional paper-making machine. The term “paper” is used to mean a fibrous flexible sheet made by depositing an aqueous suspension or slurry of fibrous material onto a fine screen to produce the flexible sheets. The slurry with the desired proportion of aramid fibrids and crystallized mineral silicate platelet particles is provided to the headbox of the paper making machine and then wet-laid onto a paper making wire. The paper-making slurry may further include aramid floc. The term “floc” is used to mean fibers that are cut to a short length and which are customarily used in the preparation of wet-laid sheets. Typically, floc has a length of from about 3 to about 20 mm, and a preferred length of about 3 to about 7 mm. Floc is normally produced by cutting continuous fibers into the required lengths using well-known methods in the art. In a preferred slurry, the solids of the slurry are comprised of 40 to 80 weight percent of the crystallized mineral silicate platelets, 20 to 60 weight percent meta-aramid fibrids, and 0 to 20 weight percent meta-aramid floc, all based on the total solids weight of the dispersion. Exemplary fire resistant paper sheets comprised of aramid fibrids and mica particles are disclosed in U.S. Pat. Nos. 6,312,561 and 6,991,845. Such fire resistant paper sheets generally have a basis weight of 90 to 200 g/m² and a thickness of from 75 to 350 microns.

The fire resistant sheet preferably has an average thickness of at least 75 microns (2.95 mils), and more preferably of at least 90 microns (3.54 mils), even more preferably of at least 100 microns (3.94 mils) and even more preferably at least 125 microns (4.92 mils) and even more preferably at least 150 microns (5.91 mils). The thickness of the layer is chosen in order to meet the desired flame protection and electrical insulation properties while balancing against the increased cost and lower flexibility of thicker layers.

Flame resistant additives such as organic flame retardants (phosphorous-based, phosphorus and halogen-based, chlorine-based, bromine-based) or inorganic flame retardants (aluminum hydroxide, magnesium hydroxide, zinc borate, or antimony-based, guanidine-based or zirconium-based fire retardants) may be incorporated into the fire resistant sheet to provide additional resistance to flame and burning of the polymer fibrids and floc. Likewise, other additives, e.g. processing aids (e.g., oligomers), antioxidants, light stabilizers, anti-static agents, heat stabilizers, ultraviolet absorbing agents, fillers or various reinforcing agents may be added to the fribrids or floc when made as long as they do not substantially detract from the ability of the fire resistant paper to provide the required burn resistance and electrical insulation.

The disclosed back-sheet further comprises a fluoropolymer film laminated to the above-described fire resistant sheet. As used herein fluoropolymers are polymers made from at least one fluorinated monomer (fluoromonomer), i.e., wherein at least one of the monomers contains fluorine, preferably an olefinic monomer with at least one fluorine or a perfluoroalkyl group attached to a doubly-bonded carbon. The fluorinated monomer is generally selected from the group of tetrafluoroethylene (TFE), hexafluoropropylene (HFP), chlorotrifluoroethylene (CTFE), trifluoroethylene, hexafluoroisobutylene, perfluoroalkyl ethylene, fluorovinyl ethers, vinyl fluoride (VF), vinylidene fluoride (VF2), perfluoro-2,2-dimethyl-1,3-dioxole (PDD), perfluoro-2-methylene-4-methyl-1,3-dioxolane (PMD), perfluoro(allyl vinyl ether) and perfluoro(butenyl vinyl ether). Non-fluorinated olefinic comonomers such as ethylene and propylene can be copolymerized with fluorinated monomers. Fluoropolymers such as polyvinyl fluoride, polyvinylidene fluoride (PVF), polytetrafluoroethylene, ethylene-tetrafluoroethylene copolymers are preferred for the fluoropolymer film. Suitable PVF films are more fully disclosed in U.S. Pat. No. 6,632,518. The preferred fluoropolymer films of the disclosed back-sheet are fluoropolymer films with melting or decomposition temperatures of 200° C. or more.

The fluoropolymer film may include up to 25% by weight of other polymers that are not fluoropolymers, such as thermoplastic adhesive polymers, and may further contain minor amounts of any additive known within the art. Such additives include, but are not limited to, plasticizers, processing aides, flow enhancing additives, lubricants, pigments, dyes, flame retardants, impact modifiers, nucleating agents to increase crystallinity, antiblocking agents such as silica, thermal stabilizers, hindered amine light stabilizers (HALS), UV absorbers, UV stabilizers, dispersants, surfactants, chelating agents, coupling agents, adhesives, primers, reinforcement additives such as glass fiber, fillers and the like.

The thickness of the fluoropolymer film is not critical and may be varied depending on the particular application. Generally, the thickness of the polymeric film will range from about 0.1 to about 10 mils (about 2.5 to 254 microns). The fluoropolymer film thickness may be preferably within the range of about 1 mil (25 microns) to about 4 mils (101 microns).

In one preferred embodiment, the fire resistant sheet has two opposite sides, the first side of which is adhered to a fluoropolymer film as discussed above, and the second side of which is adhered to a second polymeric film.

Such second polymeric film may be comprised of polyester, polycarbonate, polypropylene, polyethylene, polypropylene, cyclic polyloefins, norbornene polymers, polystyrene, syndiotactic polystyrene, styrene-acrylate copolymers, acrylonitrile-styrene copolymers, poly(ethylene naphthalate), polyethersulfone, polysulfone, nylons, poly(urethanes), acrylics, cellulose acetates, cellulose triacetates, cellophane, vinyl chloride polymers, polyvinylidene chloride, vinylidene chloride copolymers, and fluoropolymers such as polyvinyl fluoride, polyvinylidene fluoride, polytetrafluoroethylene, ethylene-tetrafluoroethylene copolymers and the like. Preferred polymeric films for the second polymer film include bi-axially oriented poly(ethylene terephthalate) (PET) film and fluoropolymer films such as polyvinyl fluoride (PVF) film or polyvinylidene fluoride (PVDF) film. The thickness of such other polymeric film layers is not critical and may be varied depending on the particular application. Generally, the thickness of the second polymeric film will range from about 0.1 to about 10 mils (about 2.5 to 254 microns). The polymer film(s) may further contain any additive known within the art. Such additives include, but are not limited to, plasticizers, processing aides, flow enhancing additives, lubricants, pigments, dyes, flame retardants, impact modifiers, nucleating agents to increase crystallinity, antiblocking agents such as silica, thermal stabilizers, hindered amine light stabilizers (HALS), UV absorbers, UV stabilizers, dispersants, surfactants, chelating agents, coupling agents, adhesives, primers, reinforcement additives such as glass fiber, fillers and the like.

The method of laminating the fire resistant sheet and the fluoropolymer film and/or the second polymeric film may be any method known in the art. In one embodiment, an adhesive is used for bonding the fire resistant sheet to the other polymeric film layer(s). The bonding method or bonding adhesive will depend on the composition of the film layers being bonded. A secure bond is needed that will not delaminate after years, and even decades, of outdoor exposure. Where the back-sheet includes a fire resistant film sheet, as disclosed above, bonded to a fluoropolymer film layer, the layers may be bonded by applying a primer layer of an amine functional acrylic polymer to the fluoropolymer film, applying a thermoplastic adhesive layer containing acid modified polyolefin to the primer layer, and adhering the thermoplastic adhesive to the fire resistant sheet. Where the fire resistant sheet is bonded on its second side to another polymer film, other conventional adhesives known in the art may be used, such as polyurethane, acrylic and epoxy adhesives.

The adhesives may be applied through melt processes or through solution, emulsion, dispersion, and the like, coating processes. One of ordinary skill in the art will be able to identify appropriate process parameters based on the composition and process used for the coating formation. The process conditions and parameters for making coatings by any method in the art are determined by a skilled artisan for any given composition and desired application. For example, the adhesive or primer compositions can be cast, sprayed, air knifed, brushed, rolled, poured or printed or the like onto the film or sheet surface. Generally the adhesive or primer is diluted into a liquid media prior to application to provide uniform coverage over the surface. The liquid media may function as a solvent for the adhesive or primer to form solutions or may function as a non-solvent for the adhesive or primer to form dispersions or emulsions. Adhesive coatings may also be applied by spraying the molten, atomized adhesive or primer composition onto the film or sheet surface. The adhesive layer thickness may be in the range of 2 to 75 microns, preferably 5 to 50 microns, and more preferably 10-25 microns.

In one embodiment, the DuPont acrylic adhesive 68040 solution (from E. I. du Pont de Nemours and Company) diluted with an equal amount of toluene was brushed onto one side of the fire resistant sheet and air dried at room temperature. A polymeric PVF film or other polymeric film can be adhered by placing the film over the dried adhesive layer and the sheet and film can be laminated to each other by placing them in a vacuum platen press at about 5 tons of force and about 150° C. for about 5 minutes.

The fluoropolymer film and the second polymer film are preferably stress-relieved and shrink-stable under the coating and lamination processes. Preferably, the polymeric films are heat stabilized to provide low shrinkage characteristics when subjected to elevated temperatures (i.e. less than 2% shrinkage in both directions after 30 min at 150°). In addition, one or more of the film layers may be coated on the polymeric films of the disclosed back-sheet in order to improve desired properties such as dielectric properties or oxygen or moisture barrier properties. For example, metal oxide coatings, such as those disclosed in U.S. Pat. Nos. 6,521,825; and 6,818,819 may function as oxygen and moisture barriers when coated on the polymer film surfaces.

Metal foil layers, such as an aluminum foil, may be additionally incorporated into the back-sheet. If desired, a layer of non-woven glass fiber (scrim) may also be incorporated into the disclosed fire resistant backsheet.

In a preferred back-sheet, the fire resistant sheet is laminated between the polymeric film layers. For example, as shown in FIG. 2, the back-sheet 20 comprises a fire resistant sheet layer 24 comprising crystallized mineral silicate platelet particles, as described above, that is laminated between polymeric film layers 22 and 26. In one preferred embodiment, each of the polymeric film layers 22 and 26 are fluoropolymer films such as PVF films. In another preferred embodiment, the outwardly facing polymer film layer 22 is a fluoropolymer film such as a PVF film while the other polymeric film layer that will be adhered to the encapsulant layer 18 of a photovoltaic module is comprised of another polymer that can be adhered to both the encapsulant layer 18 and the fire resistant film sheet 24. For example, the polymeric film layer 26 may be a polyester film, such as a PET film, that contributes good moisture barrier properties to the photovoltaic module back-sheet.

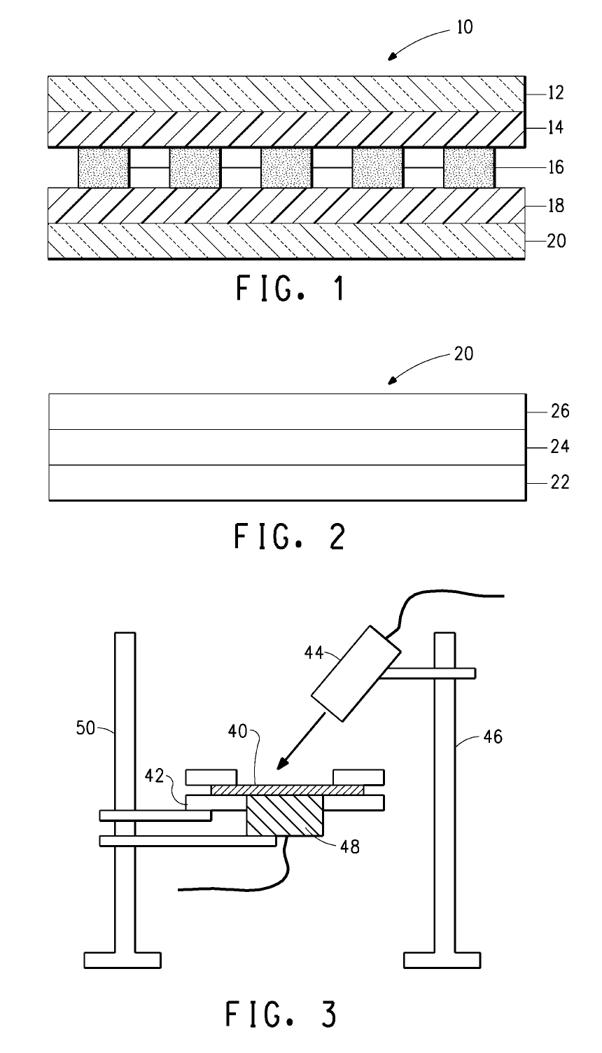

The back-sheet 20 is normally bonded to the encapsulant layer 18 (shown in FIG. 1) of the photovoltaic module via a bonding layer (not shown). Where the encapsulant layer comprises ethylene-vinyl acetate copolymer, suitable materials used for forming the bonding layer are ethylene copolymer materials, which may be selected from the following groups:

ethylene-C₁₋₄ alkyl methacrylate copolymers and ethylene-C₁₋₄ alkyl acrylate copolymers, for example, ethylene-methyl methacrylate copolymers, ethylene-methyl acrylate copolymers, ethylene-ethyl methacrylate copolymers, ethylene-ethyl acrylate copolymers, ethylene-propyl methacrylate copolymers, ethylene-propyl acrylate copolymers, ethylene-butyl methacrylate copolymers, ethylene-butyl acrylate copolymers, and mixtures of two or more copolymers thereof, wherein copolymer units resulting from ethylene account for 50%-99%, preferably 70%-95%, by total weight of each copolymer;

ethylene-methacrylic acid copolymers, ethylene-acrylic acid copolymers, and blends thereof, wherein copolymer units resulting from ethylene account for 50-99%, preferably 70-95%, by total weight of each copolymer;

ethylene-maleic anhydride copolymers, wherein copolymer units resulted from ethylene account for 50-99%, preferably 70-95%, by total weight of the copolymer;

polybasic polymers formed by ethylene with at least two co-monomers selected from C₁₋₄ alkyl methacrylate, C₁₋₄ alkyl acrylate, ethylene-methacrylic acid, ethylene-acrylic acid and ethylene-maleic anhydride, non-restrictive examples of which include, for example, terpolymers of ethylene-methyl acrylate-methacrylic acid (wherein copolymer units resulting from methyl acrylate account for 2-30% by weight and copolymer units resulting from methacrylic acid account for 1-30% by weight), terpolymers of ethylene-butyl acrylate-methacrylic acid (wherein copolymer units resulting from butyl acrylate account for 2-30% by weight and copolymer units resulting from methacrylic acid account for 1-30% by weight), terpolymers of ethylene-propyl methacrylate-acrylic acid (wherein copolymer units resulting from propyl methacrylate account for 2-30% by weight and copolymer units resulting from acrylic acid account for 1-30% by weight), terpolymers of ethylene-methyl acrylate-acrylic acid (wherein copolymer units resulting from methyl acrylate account for 2-30% by weight and copolymer units resulted from acrylic acid account for 1-30% by weight), terpolymers of ethylene-methyl acrylate-maleic anhydride (wherein copolymer units resulting from methyl acrylate account for 2-30% by weight and copolymer units resulting from maleic anhydride account for 0.2-10% by weight), terpolymers of ethylene-butyl acrylate-maleic anhydride (wherein copolymer units resulting from butyl acrylate account for 2-30% by weight and copolymer units resulted from maleic anhydride account for 0.2-10% by weight), and terpolymers of ethylene-acrylic acid-maleic anhydride (wherein copolymer units resulting from acrylic acid account for 2-30% by weight and copolymer units resulting from maleic anhydride account for 0.2-10% by weight);

copolymers formed by ethylene and glycidyl methacrylate with at least one co-monomer selected from C₁₋₄ alkyl methacrylate, C₁₋₄ alkyl acrylate, ethylene-methacrylic acid, ethylene-acrylic acid, and ethylene-maleic anhydride, non-restrictive examples of which include, for example, terpolymers of ethylene-butyl acrylate-glycidyl methacrylate, wherein copolymer units resulting from butyl acrylate account for 2-30% by weight and copolymer units resulting from glycidyl methacrylate account for 1-15% by weight;

and blends of two or more above-described materials.

The thickness of the bonding layer suitable for bonding back-sheet to the encapsulant layer may be 10 to 400 microns, preferably 40 to 200 microns. The bonding layer may contain various types of additives. Suitable non-restrictive examples are photo-stabilizers, thermal stabilizers, UV stabilizers, antioxidants, slip agents, light reflecting additives, and pigments. There are no specific restrictions to the content of the additives in the bonding layer, as long as the additives do not produce an adverse impact on the bonding layer or final bonding properties.

The bonding layer may be bonded to the back-sheet by using any method known in the art. Non-restrictive examples of suitable bonding methods include, for example, melting suitable copolymer resin in an extruder and then coating the melt on the back-sheet surface by extrusion through an extruder die, or adhering the bonding layer to the back-sheet with an adhesive.

The encapsulant layers 14 and 18 of the photovoltaic module are typically comprised of ethylene methacrylic acid and ethylene acrylic acid, ionomers derived therefrom, or combinations thereof. Such encapsulant layers may also be films or sheets comprising poly(vinyl butyral)(PVB), ethylene vinyl acetate (EVA), poly(vinyl acetal), polyurethane (PU), linear low density polyethylene, polyolefin block elastomers, ethylene acrylate ester copolymers, such as poly(ethylene-co-methyl acrylate) and poly(ethylene-co-butyl acrylate), ionomers, silicone polymers and epoxy resins. As used herein, the term “ionomer” means and denotes a thermoplastic resin containing both covalent and ionic bonds derived from ethylene/acrylic or methacrylic acid copolymers. In some embodiments, monomers formed by partial neutralization of ethylene-methacrylic acid copolymers or ethylene-acrylic acid copolymers with inorganic bases having cations of elements from Groups I, II, or III of the Periodic table, notably, sodium, zinc, aluminum, lithium, magnesium, and barium may be used. The term ionomer and the resins identified thereby are well known in the art, as evidenced by Richard W. Rees, “Ionic Bonding In Thermoplastic Resins”, DuPont Innovation, 1971, 2(2), pp. 1-4, and Richard W. Rees, “Physical 30 Properties And Structural Features Of Surlyn lonomer Resins”, Polyelectrolytes, 1976, C, 177-197. Other suitable ionomers are further described in European patent EP1781735. The encapsulant layers typically have a thickness greater than or equal to 20 mils (508 microns). The encapsulant layers may further contain any additive known within the art. Such exemplary additives include, but are not limited to, plasticizers, processing aides, flow enhancing additives, lubricants, pigments, dyes, flame retardants, impact modifiers, nucleating agents to increase crystallinity, antiblocking agents such as silica, thermal stabilizers, hindered amine light stabilizers (HALS), UV absorbers, UV stabilizers, dispersants, surfactants, chelating agents, coupling agents, adhesives, primers, reinforcement additives such as glass fiber, fillers and the like.

The photovoltaic cell layer 16 (also know as the active layer) is made of an ever increasing variety of materials. Within the present invention, a solar cell is meant to include any article which can convert light into electrical energy. Typical art examples of the various forms of solar cells include, for example, single crystal silicon solar cells, polycrystal silicon solar cells, microcrystalline silicon solar cells, amorphous silicon based solar cells, copper indium (gallium) diselenide solar cells, cadmium telluride solar cells, compound semiconductor solar cells, dye sensitized solar cells, and the like. The most common types of solar cells include multi-crystalline solar cells, thin film solar cells, compound semiconductor solar cells and amorphous silicon solar cells due to relatively low cost manufacturing ease for large scale solar cells. Thin film solar cells are typically produced by depositing several thin film layers onto a substrate, such as glass or a flexible film, with the layers being patterned so as to form a plurality of individual cells which are electrically interconnected to produce a suitable voltage output. Depending on the sequence in which the multi-layer deposition is carried out, the substrate may serve as the rear surface or as a front window for the solar cell module.

The photovoltaic module may further comprise one or more sheet layers or film layers to serve as the light-transmitting substrate 12 (also know as the incident layer or the front sheet). The light-transmitting layer 12 may be comprised of glass or plastic sheets, such as, polycarbonate, acrylics, polyacrylate, cyclic polyolefins, such as ethylene norbornene polymers, polystyrene, polyamides, polyesters, fluoropolymers and the like and combinations thereof. Glass most commonly serves as the incident layer of the photovoltaic solar module. The term “glass” is meant to include not only window glass, plate glass, silicate glass, sheet glass, low iron glass, tempered glass, tempered CeO-free glass, and float glass, but also includes colored glass, specialty glass which includes ingredients to control, for example, solar heating, coated glass with, for example, sputtered metals, such as silver or indium tin oxide, for solar control purposes, E-glass, Toroglass, Solex® glass (a product of Solutia) and the like. The type of glass to be selected for a particular laminate depends on the intended use.

A process of manufacturing the photovoltaic module with the disclosed fire resistant back-sheet will now be disclosed. The photovoltaic module may be produced through autoclave and non-autoclave processes. For example, the photovoltaic module constructs described above may be laid up in a vacuum lamination press and laminated together under vacuum with heat and standard atmospheric or elevated pressure. In an exemplary process, a glass sheet, a front-sheet encapsulant layer, a photovoltaic cell layer, a back-sheet encapsulant layer and a fire resistant back-sheet as disclosed above are laminated together under heat and pressure and a vacuum (for example, in the range of about 27-28 inches (689-711 mm) Hg) to remove air. Preferably, the glass sheet has been washed and dried. A typical glass type is 90 mil thick annealed low iron glass. In an exemplary procedure, the laminate assembly of the present invention is placed into a bag capable of sustaining a vacuum (“a vacuum bag”), drawing the air out of the bag using a vacuum line or other means of pulling a vacuum on the bag, sealing the bag while maintaining the vacuum, placing the sealed bag in an autoclave at a temperature of about 120° C. to about 180° C., at a pressure of about 200 psi (about 15 bars), for from about 10 to about 50 minutes. Preferably, the bag is autoclaved at a temperature of from about 120° C. to about 160° C. for 20 minutes to about 45 minutes. More preferably, the bag is autoclaved at a temperature of from about 135° C. to about 160° C. for about 20 minutes to about 40 minutes.

Air trapped within the laminate assembly may be removed through a nip roll process. For example, the laminate assembly may be heated in an oven at a temperature of about 80° C. to about 120° C., or preferably, at a temperature of between about 90° C. and about 100° C., for about 30 minutes. Thereafter, the heated laminate assembly is passed through a set of nip rolls so that the air in the void spaces between the photovoltaic module outside layers, the photovoltaic cell layer and the encapsulant layers may be squeezed out, and the edge of the assembly sealed. This process may provide the final photovoltaic module laminate or may provide what is referred to as a pre-press assembly, depending on the materials of construction and the exact conditions utilized.

The pre-press assembly may then be placed in an air autoclave where the temperature is raised to about 120° C. to about 160° C., or preferably, between about 135° C. and about 160° C., and the pressure is raised to between about 100 psig and about 300 psig, or preferably, about 200 psig (14.3 bar). These conditions are maintained for about 15 minutes to about 1 hour, or preferably, about 20 to about 50 minutes, after which, the air is cooled while no more air is added to the autoclave. After about 20 minutes of cooling, the excess air pressure is vented and the photovoltaic module laminates are removed from the autoclave. The described process should not be considered limiting. Essentially, any lamination process known within the art may be used to produce the fire resistant photovoltaic modules disclosed herein.

If desired, the edges of the photovoltaic module may be sealed to reduce moisture and air intrusion by any means known within the art. Such moisture and air intrusion may degrade the efficiency and lifetime of the photovoltaic module. Edge seal materials include, but are not limited to, butyl rubber, polysulfide, silicone, polyurethane, polypropylene elastomers, polystyrene elastomers, block elastomers, styrene-ethylene-butylene-styrene (SEBS), and the like.

### EXAMPLES

The following Examples are intended to be illustrative of the present invention, and are not intended in any way to limit the scope of the present invention.

The fire resistant sheet structures of the Examples are described below.

### Example 1

A flexible mica sheet was obtained from PAMICA Electric Material (Hubei) Co., Ltd. (Xianning, China) under the product code PB5161. The mica sheet was comprised of 90% by weight of muscovite mica based on the weight of the sheet, and the sheet was impregnated with 8% by weight of high temperature resistant organic silicone resin based on the weight of the sheet. The average density of the sheet was 1.9 g/cm³ and the basis weight was about 381 g/m². The sheet thickness was 7.9 mils (201 microns).

### Example 2

A flexible mica sheet was obtained from PAMICA Electric Material (Hubei) Co., Ltd. (Xianning, China) under the product code PJ5161. The mica sheet was comprised of 90% by weight of phlogopite mica based on the weight of the sheet, and the sheet was impregnated with 8% by weight of high temperature resistant organic silicone resin based on the weight of the sheet. The average density of the sheet was 1.9 g/cm³ and the basis weight was about 381 g/m². The sheet thickness was 7.9 mils (201 microns).

### Example 3

A flexible glass backed mica sheet was obtained from PAMICA Electric Material (Hubei) Co., Ltd. (Xianning, China) under the product code S140G32. The mica sheet was comprised of 90% by weight of mica based on the weight of the sheet, and the sheet was impregnated with 8% by weight of high temperature resistant organic silicone resin based on the weight of the sheet. The basis weight was about 195 g/m². The sheet thickness was 5.8 mils (147 microns).

### Examples 4 and 5

An appropriate quantity of MicroLite HTS (W. R. Grace & Co) aqueous exfoliated vermiculite dispersion, was draw down on cellulose acetate film to give wet vermiculite films of about 40 mil (1.02 mm) thicknesses. The wet films were dried overnight at room temperature and then dried over a second night in an oven at 120° C. to remove residual moisture. Dry films of 4.5 mils (114 microns)(Ex. 4) and 5 mils (127 microns)(Ex. 5) thickness resulted and were used for further testing. The cellulose acetate film was removed from the vermiculite sheets.

### Example 6

A sheet of Nomex® 418 aramid paper with about 50% by weight mica particles was obtained from E. I. du Pont de Nemours and Company, Wilmington, Del. The sheet thickness was 3 mils (76 microns).

### Example 7

A sheet of Nomex® 418 aramid paper with about 50% by weight mica particles was obtained from E. I. du Pont de Nemours and Company, Wilmington, Delaware. The sheet thickness was 5 mils (127 microns).

### Back-Sheet Construction

Cut samples of the fire resistant sheets of Examples 1-7 were coated with DuPont 68040 acrylic (E. I. du Pont de Nemours and Company, Wilmington, Del.) adhesive solution which had been diluted with an equal amount of toluene. The coating was accomplished by uniformly brushing the diluted adhesive solution on one side of the cut samples using a foam brush, followed by air drying for 1.5 hours at room temperature, then flipping the sheet sample over and brushing the other side with the diluted acrylic adhesive solution followed by air drying. The adhesive coated samples were then placed between letter size sheets of Tedlar® WP10BH9 PVF 1 mil (25 microns) thick polyvinylfluoride film (E. I. du Pont de Nemours and Company, Wilmington, Del.) with the treated side of the Tedlar® film facing the adhesive (hereafter referred to as TXT construction) followed by lamination in a Tetrahedron 20 ton vacuum platen press at 5 tons force and 150° C. for 5 minutes (press layup—SS plate/20 mil Duofoil™ release sheet/TXT/20 mil Duofoil™ release sheet/SS plate). The resulting laminated TXT samples were typically cut to 20 cm by 20 cm size for testing.

### Comparative Example 1

A control sample laminate of 1.5 mil (38 microns) thick Tedlar® polyvinylfluoride film/5 mil (127 microns) thick polyethylene terepthalate/1.5 mil (38 microns) thick Tedlar® polyvinylfluoride was obtained from Krempel GmbH (Germany).

### Mini Module Assemblies

Mini PV modules where constructed where each had a back-sheet comprised of one of the TXT samples made in accordance with Examples 1, 2, 3, 6 and 7, and Comparative Example 1. The module layup was as follows: glass substrate/EVA sheet/solar cell/EVA sheet/TXT sample. The glass substrate was a conventional front side PV module glass substrate that was about ⅛ inch (3.2 mm) thick and a 7 inch×7 inch (17.8 cm×17.8 cm) area. Both EVA sheets were 18 mil (457 microns) thick EVA sheets cut to the size of the glass. The solar cell was a conventional 6⅛ inch×6⅛ inch (15.6 cm×15.6 cm) crystalline silicon wafer with a dark blue color. The lamination was conducted in a vacuum platen press at about 5 tons force and about 150° C. for about 5 minutes. Each mini module area was about 7 inches×7 inches (17.8 cm×17.8 cm).

### Testing

Flame testing of the laminated TXT samples and of the mini modules was conducted by a specially constructed testing rig (shown in FIG. 3) in a lab hood. A two piece sample holder 42 and a K type thermocouple disk 48 were mounted on a steel ring (not shown) that was clamped on a stand 50.

Each of the TXT samples was cut down to ˜6×6 inch (15.25 cm×15.25 cm) to fit into the two piece sample holder for testing. The TXT sample 40 was placed in the sample holder 42. The sample holder sat on the steel ring while the thermocouple disk was supported/adjusted inside the ring to provide a couple of mm of contact to the back of the TXT sample.

Each of the mini modules was fit into the two piece sample holder for testing. The mini module was placed in the sample holder 42 with the glass side up in a manner like that described for the TXT sample 40 above. The sample holder sat on the steel ring while the thermocouple disk was supported/adjusted inside the ring to provide a couple of mm of contact to the back of the mini module.

An approximately 2 inch (5.1 cm) diameter natural gas jet nozzle 44 was aimed at the TXT sample at an about 45 degree angle from the top to the TXT sample and spaced ˜1 inch (˜2.5 cm) above the TXT sample.

For the mini module testing, the 2 inch (5.1 cm) diameter natural gas jet nozzle 44 was aimed at the center of the glass side of the mini module at an about 45 degree angle from the top to the module and spaced ˜1 inch (˜2.5 cm) above the module.

A computer with data acquisition software recorded time and sample temperature data. The burner gas flow was calibrated (adjusted) to obtain 2.0 cal/cm² heat flux on the thermocouple disk prior to testing of each TXT sample or mini module. An initial calibration sample prepared with a 2 mil (51 microns) stainless steel foil with 1 mil (25 microns) Tedlar® film facing the flame (threat) was used for the calibration. A five minute burn was then conducted on the TXT sample or the mini module and the thermocouple readings taken over this period were recorded.

After flame testing, the TXT samples were rated as follows:
If the TXT sample showed cracks/breaks from above or below before five minutes, the test was stopped shortly thereafter and the sample was given a fail (F) rating.
If the TXT sample completed the five minute burn test without apparent cracks at the end of the burn while the TXT sample was still in the holder, but with minor cracks/breaks following removal from the holder, it was given a medium (C) rating.
If the TXT sample completed the five minute burn test without apparent cracks at the end of the burn while the TXT sample was still in the holder, and did not have apparent cracks/breaks following removal from the holder, it was given a good (A) rating.

The ratings for the TXT samples are set forth in Table 1 below. TXT samples which were rated good or medium (A or C) were considered to be acceptable, with those rated (A) were considered preferred. The fire resistant sheet structures of Examples 1-5 and 7 received a rating of “A” and the sheet of Example 6 received a “C” rating.

After flame testing, the mini modules were rated as follows:
If smoke and flame broke out during testing, the test was stopped shortly thereafter and the mini module was given a fail (F) rating.
If there was some smoking or dripping, but no flame break out, the mini module was given a medium (C) rating.
If there was no cracked glass during the test, and the mini module did not have apparent cracks/breaks following removal from the holder, it was given a good (A) rating.

### Corona Discharge

Corona breakdown was measured with a test method used for measuring the dielectric breakdown of solid electrical insulating materials under direct-voltage stress. ASTMD1868 was followed. TXT samples of Examples 1-7 were tested. The Partial Discharge Inception Voltage (CIV) and the Partial Discharge Extinction Voltage (CEV) was measured using a HiPotronics Model 705-2 CF 5 kV Corona Free Power Supply with a Biddle Instruments Series 6627000 partial discharge detector. The TXT sample film being evaluated was placed between two brass electrodes. The humidity around the sample was controlled at 50% relative humidity and the temperature was maintained at 25° C. An increasing applied test voltage was applied to the electrodes starting from a low voltage. The voltage was increased at a steady rate until the breakdown occurred. The voltage at which there was an increase in the current flow followed by arcing was recorded as the CIV. The voltage was then gradually decreased until the breakdown ceased. The voltage at which the corona discharge ended was recorded as the CEV. The voltage is measured in volts. Generally, CIVs of 600 volts are higher were considered desirable. Lower values (e.g., 200 volts) may be acceptable depending on the application. The CIVs for Examples 1-7 were each well above 600 volts.

TABLE 1

| | | | | | | | Mini |
|---|---|---|---|---|---|---|---|
| | | Silicate | X Layer | TXT | TXT | TXT | Mod. |
| | X Sheet | Particles | Thickness | Rating | CIV | CEV | Rating |
| Example | Material | wt % | (mils) | (ACF) | (V) | (V) | (ACF) |
| Ex 1 | Mica PB6561 | >90% | 7.9 | A | 1325 | 1200 | A |
| | flexible sheet | | | | | | |
| Ex 2 | Mica PJ5161 | >90% | 7.9 | A | 1125 | 1050 | A |
| | flexible sheet | | | | | | |
| Ex 3 | Mica S140G32 | >90% | 5.8 | A | 1275 | 1150 | A |
| | glass backed | | | | | | |
| | sheet | | | | | | |
| Ex 4 | Vermiculite | 100% | 4.5 | A | 380 | 320 | — |
| | sheet | | | | | | |
| Ex 5 | Vermiculite | 100% | 5.0 | A | 200 | 80 | — |
| | sheet | | | | | | |
| Ex 6 | Nomex ® 418 | ~50% | 3.0 | C | 900 | 825 | C |
| | paper | | | | | | |
| Ex 7 | Nomex ® 418 | ~50% | 4.0 | A | 1100 | 1000 | A |
| | paper | | | | | | |
| Comp Ex 1 | TPT | 0% | 5.0 thick | F | — | — | F |
| | | | PET layer | | | | |

The data in Table 1 illustrates that the fire resistant back-sheets of the examples provide both acceptable levels of flame resistance and electrical insulation properties.

What is claimed is:

1. A back-sheet for a photovoltaic module comprising:
a fire resistant sheet comprising 40 to 100 weight percent of crystallized mineral silicate platelets based on the weight of the fire resistant sheet, said fire resistant sheet having an average thickness of at least 75 microns; and
a fluoropolymer film adhered to said fire resistant polymeric film.

2. The back-sheet of claim 1 wherein the crystallized mineral silicate platelets of said flame resistant sheet are selected from the group of mica, vermiculite, clay, talc, and combinations thereof.

3. The back-sheet of claim 1 wherein said crystallized mineral silicate platelets of said flame resistant sheet are mica particles.

4. The back-sheet of claim 3 wherein said flame resistant sheet is a flexible sheet comprised of at least 70% by weight mica based on the weight of the flame resistant sheet.

5. The back-sheet of claim 1 wherein said crystallized mineral silicate platelets are vermiculite particles.

6. The back-sheet of claim 5 wherein said flame resistant sheet is a flexible sheet comprised of at least 70% by weight vermiculite based on the weight of the flame resistant sheet.

7. The back-sheet of claim 1 wherein said crystallized mineral silicate platelets have an average diameter of about 1 to about 500 microns and an average thickness of about 0.01 to about 2 microns, and wherein the average diameter of the mineral silicate platelets is from about 20 to about 300 times greater than the average thickness of the platelets.

8. The back-sheet of claim 1 wherein said fire resistant sheet further comprises an inorganic support scrim.

9. The back-sheet of claim 8 wherein said inorganic support scrim is comprised of glass fibers.

10. The back-sheet of claim 1 wherein said fire resistant sheet is a paper comprising polymer fibrids that do not melt at temperatures below 280° C.

11. The back-sheet of claim 10 wherein said fire resistant paper comprises meta-aramid fibrids and at least 50% by weight of crystallized mineral silicate platelets based on the weight of the fire resistant sheet.

12. The back-sheet of claim 11 wherein said crystallized mineral silicate platelets are mica particles, and wherein said fire resistant paper further comprises a meta-aramid floc.

13. The back-sheet of claim 10 wherein said polymer fibrids of said fire resistant polymeric sheet further comprise an organic flame retardant selected from phosphorous-based flame retardants, phosphorus and halogen-based flame retardants, chlorine-based flame retardants, bromine-based flame retardants and combinations thereof.

14. The back-sheet of claim 10 wherein said polymer fibrids of said fire resistant polymeric sheet further comprise an inorganic flame retardant selected from aluminum hydroxide, magnesium hydroxide, zinc borate, antimony-based flame retardants, guanidine-based flame retardants, zirconium-based flame retardants, and combinations thereof.

15. The back-sheet of claim 1 wherein said fire resistant sheet has an average thickness of at least 100 microns.

16. The back-sheet of claim 1 wherein said fluoropolymer film is a film consisting essentially of fluoropolymer selected from polyvinylfluoride, polyvinylidene fluoride, polytetrafluoroethylene, ethylene-tetrafluoroethylene and combinations thereof.

17. The back-sheet of claim 1 wherein the fire resistant sheet has two opposite sides, the first side of which is adhered to said fluoropolymer film, and the second side of which is adhered to a second polymeric film.

18. The back-sheet of claim 17 wherein said second polymeric film is a film selected from fluoropolymer films and polyester films.

19. A photovoltaic module comprising the back-sheet of claim 1.
